(19) United States
(12) Patent Application Publication
(10) Pub. No.: US 2008/0049409 A1
(43) Pub. Date: Feb. 28, 2008

(54) EM Waves/RF Interferences Circuit Module and Shielding Structure

(76) Inventors: Chin-Hao Chen, Taipei (TW); Chen Ming Chiang, Taipei (TW); Chun-Chen Chao, Taipei (TW); Young-Fuh Juang, Taipei (TW)

Correspondence Address: LAW OFFICES OF LAI AND ASSOCIATES, P.C., 5800 RANCHESTER STE 200, HOUSTON, TX, 77036, US

(21) Appl. No.: 11/767,346

(22) Filed: Jun. 22, 2007

(30) Foreign Application Priority Data
Aug. 24, 2006 (TW) 095215045

(51) Int. Cl. H05K 9/00

(52) U.S. Cl. 361/818; 174/377

(57) ABSTRACT

A circuit module and a shielding structure for electromagnetic waves or radio frequency interferences are comprised of a circuit board and electronic components disposed on the circuit board, and a metal partition mounted on the electronic components; the metal partition disposed with one or a plurality of through holes, which does not contact the electronic components so as to shield electromagnetic waves or radio frequency interferences externally radiated from the electronic components, or radiated from an external source by the conductivity of the metal partition; and the through hole dissipates heat generated by the electronic components to maintain normal working status and quality of the circuit module.

### BACKGROUND OF THE INVENTION

(a) Field of the Invention

The present invention relates to a circuit module and shielding structure for Electromagnetic waves or Radio Frequency interferences, and more particularly, to the reduction of EM waves or RF interferences by metal shielding effects.

(b) Description of the Prior Art

Operation of electronic devices including computer, cellular phone, or Personal Digital Assistants is becoming faster thanks to rapid advancement in technology. Also due to the increasingly compact design of electronic products, electronic components in a device are getting even closer to one another while the circuit board itself contains a highly intensive circuit arrangement. As an electronic device operates, the electronic component which works at a higher frequency creates EM waves or RF radiation, which subjects other electronic components to abnormal wear and tear, crashing, and compromised communication quality due to interference.

To effectively avoid interference factors including EM waves and radiation, a particular circuit has been proposed to attempt solving the interference problem, e.g., the prior art taught in Taiwan Patent Gazette No. 344047. FIG. 1 of the accompanying drawings for a block chart illustrates a frequency synthesizer of the prior art, adapted to a computer motherboard to reduce EMI (Electromagnetic Interference). The frequency synthesizer is composed of an input frequency divider 11, a phase frequency detector (PFD) 12, a control circuit 13, a charge pump and loop filter 14, an output frequency divider 15, a voltage control oscillator 16, an EMI control circuit 17; and a memory ROM1 to store inputted divider numeric values is provided with three memory codes, ROM-L, ROM-C, and ROM-U to respectively store numeric values of three sets of difference frequencies. The EMI control circuit 17 controls alternative changes among memory for the codes ROM-L, ROM-C, and ROM-U. Both the PFD 12 and the control circuit 13 maintain the variation of output frequency generated from the voltage control oscillator 16 at a constant rate. Therefore, the variation of frequency tends to be slow and smooth for EMI reduction. However, since complicated control circuits are adapted in the prior art to prevent EMI, the circuit architecture is substantially complicated, and the practical use is poor due to poor function or improper design of the circuit members.

Furthermore, in the attempt to solve EM waves or RF interferences, an aluminum foil to cover up the circuit board has been proposed in the prior art by providing an SMT (Surface Mount Technology) finger strip on the circuit board or a closed metal mask directly disposed on the electronic components. However, this prior art prevents merchandizing since it takes to ground on the edge of the circuit board at the cost of effectively shielding the interference sources and a larger area is needed. The use of the SMT finger strip in the prior art also suffers the problem of short circuited or damaged circuit boards because that the SMT finger strip can be easily bent or deformed. When the conventional closed metal mask is in use, electronic components may be overheated due to poor heat dissipation.

### SUMMARY OF THE INVENTION

The primary purpose of the present invention is to provide a circuit module and shielding structure for EM waves or RF interferences to solve the problems of poor shielding results, difficulties in heat dissipation and complicated design found with the prior art, by taking advantage of metal shielding effects for EM waves or RF interference reduction and combining with a design to help heat dissipation.

To achieve the purpose, the present invention related to a circuit module is comprised of a circuit board, electronic components, and a metal partition. Electronic components are disposed on the circuit board to execute operation, process or memory functions. When the electronic component works at a faster clock, EM waves or RF interference will be radiated simultaneously. For other electronic components on the circuit board, the EM waves or RF interference will be deemed as an interference source to affect their normal operation. Therefore, a metal partition is provided in the present invention. The metal partition is erected over the electronic components without contacting them, and is disposed with at least one through hole. The conductivity of the metal partition converts EM waves or RF interferences into transient current to shield EM waves or RF interferences thus to further protect other electronic components on the circuit module. Furthermore, the through hole on the metal partition helps to dissipate heat generated from electronic components. The through hole is provided in smaller diameter for preventing EM waves or RF interference from being permeated through unless the frequency of the interference is extremely high.

The metal partition of the present invention is electrically connected to one ground end of the circuit board to guide the transient current converted from EM waves or RF interferences to the ground end. The circuit board is preferably a motherboard mounted in a computer or other electronic device; and the electronic component is preferably a CPU (central processing unit), Northbridge chipset, memory or clock generator disposed on the motherboard.

### BRIEF DESCRIPTION OF THE DRAWINGS

FIG. 1 is a block chart of a frequency synthesizer of the prior art;

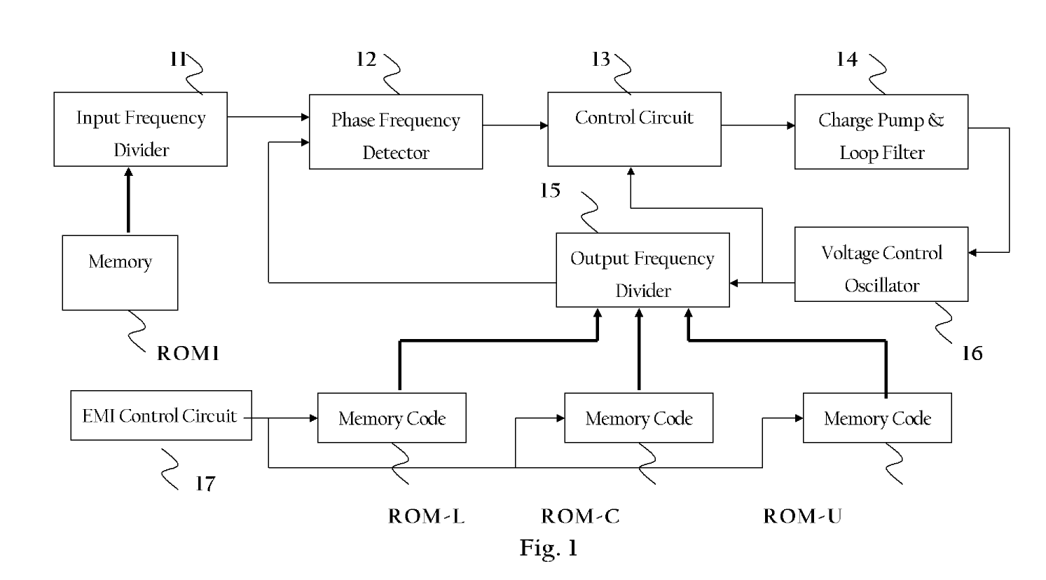

FIG. 2 is a perspective view of a preferred embodiment of the present invention;

FIG. 3 is a side view of the preferred embodiment of the present invention; and

FIG. 4 is bird's eye view of the preferred embodiment of the present invention.

### DETAILED DESCRIPTION OF THE PREFERRED EMBODIMENTS

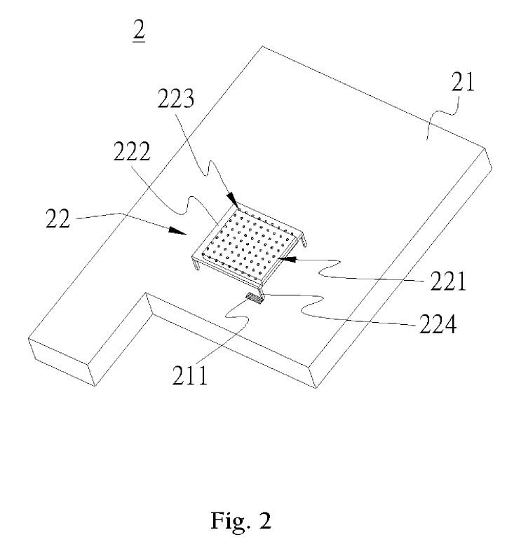

Referring to FIG. 2 for a perspective view of a circuit module and shielding structure for EM waves or RF interferences of the present invention, a circuit module 2 is comprised of a circuit board 21 and a shielding structure 22. The shielding structure 22 includes an electronic component 221, a metal partition 222, and a conduction post 224. The electronic component 221 adapted to the circuit board 21 is provided to execute operation, process or memory functions. When the electronic component 221 is working at a faster clock, it will radiate EM waves or RF interference at the same time to the area outside the electronic component 221. To other electronic components on the circuit board, the electronic component 211 radiating EM waves or RF interferences becomes an interference source. The metal partition 222 is disposed with one or a plurality of through holes 223 and all the ends of the metal partition 222 are vertically connected to the conduction post 224 so that the metal partition 222 may be erected over but not contacting the electronic component 221. Whereas the metal partition 222 is provided with inherited conductivity, it is capable of converting those EM waves or RF interferences into transient current thus to achieve the purpose of shielding EM waves or RF interferences. One or a plurality of ends from the conduction post 224 are electrically connected to the metal partition 222 while the other end of conduction post 224 is electrically connected to a ground end 211 to guide the transient current converted from those EM waves or RF interference to the ground end 211. The heat generated from the active electronic component 221 is dissipated via the through hole 223 to prevent possible damage or compromised performance due to the collected heat without dissipation. Whereas the through hole is made in a smaller diameter, it is capable of preventing the risk of having those EM waves or RF interferences to escape from the through hole 223 unless the interference is at an extremely high frequency. The present invention therefore achieves the results of heat dissipation and shielding the EM waves or RF interferences. The circuit board 21 may be related to a motherboard mounted in a computer or other electronic device; the electronic component 221 may be related to a CPU, Northbridge chipset, memory or clock generator mounted on the motherboard; and the metal partition 222 may be made of aluminum or copper.

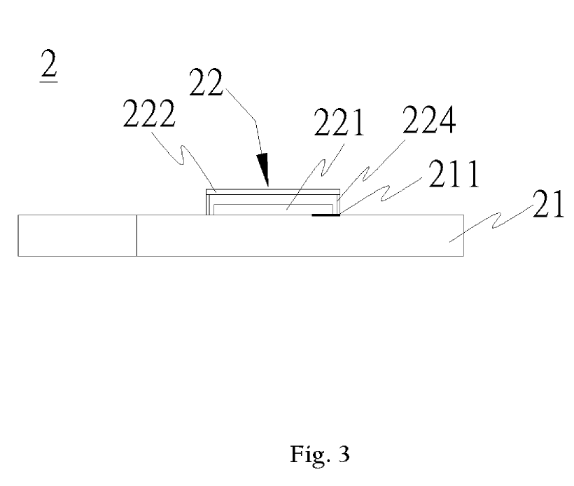

As illustrated in FIG. 3 for a side view of the present invention, the conduction post 224 is connected between the metal partition 222 and the circuit board, and is also connected to the ground end 211 of the circuit board 21. Accordingly, the metal partition 222 is positioned over but without contacting the electronic component 221, while permitting the transient current in the metal partition 222 to be guided to the ground end 211.

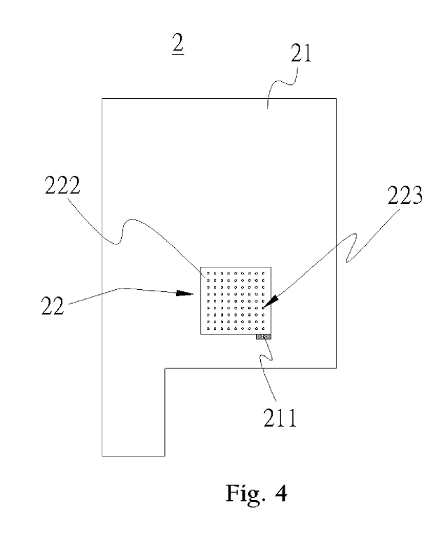

Referring to FIG. 4 for a bird's eye view of the present invention, the area of the metal partition 222 is greater than that of the electronic component 221 to fully cover up the electronic component 221 for achieving the optimal masking results.

We claim:

1. A circuit module including a circuit board, an electronic component disposed on the circuit board, and a metal partition mounted on the electronic component and provided with at least one through hole; external radiation of EM waves or RF interferences generated from the electronic component or from an external source upon the electronic component being shielded by taking advantage of the conductivity of the metal partition.

2. The circuit module as claimed in claim 1, wherein the metal partition is not contacted with the electronic component.

3. The circuit module as claimed in claim 1, wherein heat generated by the electronic component is dissipated via the through hole.

4. The circuit module as claimed in claim 1, wherein the metal partition is electrically connected to a ground end of the circuit board; and the transient current converted therefrom is guided to the ground end.

5. The circuit module as claimed in claim 1, wherein the circuit board is a motherboard.

6. The circuit module as claimed in claim 1, wherein the electronic component is a CPU, a Northbridge chipset, a memory or a clock generator.

7. An EM waves or RF interferences shielding structure adapted to a circuit module to shield a source of EM waves or RF interferences on the circuit module includes a metal partition erected over the interference source and provided with one or a plurality of through holes; and the conductivity of the metal partition shields those EM waves or RF interferences to protect the electronic components mounted on the circuit module.

8. The EM waves or RF interferences shielding structure as claimed in claim 7, wherein the metal partition and the interference are not contacting each other.

9. The EM waves or RF interferences shielding structure as claimed in claim 7, wherein heat generated from the interference source is dissipated via the through hole.

10. The EM waves or RF interferences shielding structure as claimed in claim 7, wherein the metal partition is electrically connected to a ground end of the circuit board; and the transient current converted therefrom is guided to the ground end.
